(19) United States
(12) Patent Application Publication
(10) Pub. No.: US 2007/0111387 A1
(43) Pub. Date: May 17, 2007

(54) Manufacturing method of wiring board and manufacturing method of semiconductor device

(75) Inventor: Kiyoshi Oi, Nagano (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD.

(21) Appl. No.: 11/594,074

(22) Filed: Nov. 8, 2006

(30) Foreign Application Priority Data
Nov. 9, 2005 (JP) P. 2005-325090

(51) Int. Cl. H01L 21/00

(52) U.S. Cl. 438/108; 438/613; 257/E23.06

(57) ABSTRACT

A method of manufacturing a wiring board, for mounting a semiconductor chip thereon, including coupling portions to be coupled to the semiconductor chip and a pattern wiring to be coupled to the semiconductor chip via the coupling portions, including: a feeding layer forming step of forming, on the pattern wiring, the feeding layer used for forming the coupling portions by an electrolytic plating method; a masking step of forming a mask pattern on the feeding layer; an etching step of etching the feeding layer exposed form the mask pattern; and an electrolytic plating step of forming the coupling portions on the pattern wiring exposed from the mask pattern by an electrolytic plating method.

### BACKGROUND OF THE INVENTION

The present invention relates to a wiring board on which a semiconductor chip is mounted and a semiconductor device formed by mounting a semiconductor chip on the wiring board.

At present, the improvement of the efficiency of electronic devices using semiconductor devices such as semiconductor chips has been advanced, and there are demands of high density in the case of mounting a semiconductor chip on a board and a demand of miniaturizing and reducing a space of a board mounting a semiconductor chip thereon.

Thus, when the pitch of electrodes formed on the semiconductor chip side is made narrower, there arise various problems such as the degradation of mounting reliability in the case of coupling the electrodes to coupling portions on the wiring board side via solder bumps formed at the electrodes, respectively.

For example, the size of a clearance between the semiconductor chip and the wiring board becomes smaller in accordance with the reduction of the pitch of the electrodes. Thus, there arises a problem that under fill made of resin to be permeated into the clearance hardly permeate and so voids are likely generated thereby to degrade the mounting reliability of the semiconductor chip.

In view of this problem, there have been proposed methods in each of which the thickness of the coupling portions (mounting pads) on the wiring board side to be coupled to the semiconductor chip is made large thereby to improve the mounting reliability of the semiconductor chip (see a patent document 1 to a patent document 3, for example).
[Patent Document 1] JP-A-2000-315706
[Patent Document 2] JP-A-2004-140248
[Patent Document 3] JP-A-10-163599

However, when the thickness of the coupling portions (mounting pads) formed on a pattern wiring on the wiring board side is formed to be large, a stress applied to a boundary surface between the coupling portion and the pattern wiring becomes large. Thus, the coupling portion likely exfoliates from the pattern wiring, so that it is feared that the mounting reliability at the time of mounting a semiconductor chip on a wiring board is degraded.

In particular, when the coupling portion is formed by a so-called a semi-additive process (see the patent document 1 and the patent document 2, for example), there may arise a problem that the coupling portion likely exfoliates.

According to the semi-additive process, first, a feeding layer used for feeding in the succeeding electrolytic plating process is formed thinly by the nonelectrolytic plating method, then a mask pattern is formed on the feeding layer and a desired pattern is formed by the electrolytic plating. The semi-additive method has been used widely in recent years since fine patterns can be configured efficiently.

In this case, although the coupling portion is configured by a laminated structure of a feeding layer formed by the nonelectrolytic plating method and a layer formed by the electrolytic plating method, since the feeding layer formed by the nonelectrolytic plating method is low in its adhering force, it is feared that the coupling portion exfoliates. Thus, it is difficult to form the coupling portion so as to have a large thickness (a large height) and so it is difficult to secure the mounting reliability in the case of mounting a semiconductor chip on a mounting board with a fine coupling pitch.

Accordingly, a unified object of the invention is to provide a new and useful manufacturing method of a wiring board and a manufacturing method of a semiconductor device each of which solves the aforesaid problems.

### SUMMARY OF THE INVENTION

A concrete object of the invention is to provide a wiring board which is good in mounting reliability and capable of mounting a semiconductor chip with a fine coupling pitch and also to provide a semiconductor device in which a semiconductor chip is mounted on a wiring board with a fine coupling pitch and mounting reliability is good.

In order to solve the aforesaid problems, according to the first aspect of the invention, there is provided a method of manufacturing a wiring board, for mounting a semiconductor chip thereon, including coupling portions to be coupled to the semiconductor chip and a pattern wiring to be coupled to the semiconductor chip via the coupling portions, including:

a feeding layer forming step of forming, on the pattern wiring, the feeding layer used for forming the coupling portions by an electrolytic plating method;

a masking step of forming a mask pattern on the feeding layer;

an etching step of etching the feeding layer exposed from the mask pattern; and

an electrolytic plating step of forming the coupling portions on the pattern wiring exposed from the mask pattern by an electrolytic plating method.

According to the invention, it is possible to provide a wiring board which is good in mounting reliability and capable of mounting a semiconductor chip with a fine coupling pitch.

Further, preferably, each of the coupling portions is formed by laminating a plurality of layers by an electrolytic plating method, whereby the coupling property of the coupling portion as to the pattern wiring and the semiconductor chip can be made good.

Further, preferably, the coupling portion includes a lowermost layer formed by same material formed by the same plating method as the pattern wiring, and the lowermost layer is formed so as to contact to the pattern wiring, whereby the coupling property between the coupling portion and the pattern wiring is made good.

Further, preferably, the coupling portion is formed so as to erect on the pattern wiring, thereby to cope with the mounting with a fine pitch.

Further, preferably, a height of the coupling portion is larger than a diameter of the coupling portion, thereby to be able to cope with the mounting with a further fine pitch.

Further, preferably, the feeding layer is formed on the pattern wiring and on an insulation layer covering a part of the pattern wiring, whereby the electric power at the time of the electrolytic plating can be fed via the insulation layer.

Further, preferably, there is further provided with a step of, after the electrolytic plating step, removing the mask pattern and etching away the feeding layer which is exposed in accordance with the removal of the mask pattern.

In order to solve the aforesaid problems, according to a second aspect of the invention, there is provided a method of manufacturing a semiconductor device, for mounting a semiconductor chip on a wiring board, including the semiconductor chip, coupling portions to be coupled to the semiconductor chip and a pattern wiring to be coupled to the semiconductor chip via the coupling portions, including:

a feeding layer forming step of forming, on the pattern wiring, the feeding layer used for forming the coupling portions by an electrolytic plating method;

a masking step of forming a mask pattern on the feeding layer;

an etching step of etching the feeding layer exposed from the mask pattern;

an electrolytic plating step of forming the coupling portions on the pattern wiring exposed from the mask pattern by an electrolytic plating method; and

a mounting step of coupling the semiconductor chip to the coupling portions.

According to the invention, it is possible to provide a semiconductor device in which a semiconductor chip is mounted on a wiring board with a fine coupling pitch and mounting reliability is good.

Further, preferably, the coupling portion is formed so as to erect on the pattern wiring, thereby to cope with the mounting with a fine pitch.

Further, preferably, the coupling portion is formed by laminating a plurality of layers by an electrolytic plating method, and one of the plurality of layers coupled to the semiconductor chip is formed by material different from material forming another of the plurality of layers coupled to the wiring pattern, whereby the coupling property of the coupling portion as to the pattern wiring and the semiconductor chip can be made good.

According to the invention, preferably, it becomes possible to provide the wiring board which is good in mounting reliability and capable of mounting a semiconductor chip with a fine coupling pitch and also to provide the semiconductor device in which a semiconductor chip is mounted on the wiring board with a fine coupling pitch and mounting reliability is good.

### BRIEF DESCRIPTION OF THE DRAWINGS

FIG. 1A is a diagram showing the manufacturing method of a wiring board according to the first embodiment.

FIG. 1B is a diagram showing the manufacturing method of the wiring board according to the first embodiment.

FIG. 1C is a diagram showing the manufacturing method of the wiring board according to the first embodiment.

FIG. 1D is a diagram showing the manufacturing method of the wiring board according to the first embodiment.

FIG. 1E is a diagram showing the manufacturing method of the wiring board according to the first embodiment.

FIG. 1F is a diagram showing the manufacturing method of the wiring board according to the first embodiment.

FIG. 1G is a diagram showing the manufacturing method of the wiring board according to the first embodiment.

FIG. 1H is a diagram showing the manufacturing method of the wiring board according to the first embodiment.

FIG. 1I is a diagram showing the manufacturing method of the wiring board according to the first embodiment.

FIG. 1J is a diagram showing the manufacturing method of the wiring board according to the first embodiment.

FIG. 1K is a diagram showing the manufacturing method of the wiring board according to the first embodiment.

FIG. 2 is a diagram showing the manufacturing method of a semiconductor device according to the first embodiment.

FIG. 3A is a diagram showing the manufacturing method of the wiring board according to the first embodiment.

FIG. 3B is a diagram showing the manufacturing method of the wiring board according to the first embodiment.

FIG. 3C is a diagram showing the manufacturing method of the wiring board according to the first embodiment.

FIG. 3D is a diagram showing the manufacturing method of the wiring board according to the first embodiment.

FIG. 3E is a diagram showing the manufacturing method of the wiring board according to the first embodiment.

FIG. 3F is a diagram showing the manufacturing method of the wiring board according to the first embodiment.

FIG. 3G is a diagram showing the manufacturing method of the wiring board according to the first embodiment.

FIG. 4A is a diagram showing the method of an adhesive force test.

FIG. 4B is a diagram showing the method of the adhesive force test.

FIG. 5 is a diagram showing the result of the adhesive force test.

### DETAILED DESCRIPTION OF THE PREFERRED EMBODIMENTS

The manufacturing method of a wiring board according to the invention is a method of manufacturing a wiring board on which a semiconductor chip is mounted, and the wiring board includes coupling portions to be coupled to the semiconductor chip and a pattern wiring to be coupled to the semiconductor chip via the coupling portions.

Further, the manufacturing method of a wiring board according to the invention includes: 1) a feeding layer forming step of forming, on the pattern wiring, the feeding layer used for forming the coupling portions by an electrolytic plating method; 2) a masking step of forming a mask pattern on the feeding layer; 3) an etching step of etching the feeding layer exposed form the mask pattern; and 4) an electrolytic plating step of forming the coupling portions on the pattern wiring exposed from the mask pattern by an electrolytic plating method.

According to the semi-additive method of the related art, after forming a feeding layer for the electrolytic plating, a desired pattern (coupling portions) is formed on the feeding layer by the electrolytic plating. That is, the coupling portion to be formed has a laminated structure of the feeding layer and an electrolytic plating layer.

On the other hand, in the manufacturing method of a wiring board according to the invention, as described above, after forming the feeding layer, the feeding layer at a part (exposed portion from the mask pattern) of the pattern wiring is etched away and the coupling potions are formed by the electrolytic plating. In this case, the feeding at the time of the electrolytic plating is performed via the feeding layer not being etched away (not being exposed from the mask pattern) and the pattern wiring, so that the coupling portions can be formed by the electrolytic plating without any problem.

In the manufacturing method of a wiring board according to the invention, since the electrolytic plating layer of the coupling portion is formed so as to directly contact to the pattern wiring, the adhesive force of the coupling portion to the pattern wiring is made good and so the reliability of mounting a semiconductor chip on the wiring board can be improved advantageously.

For example, when the aforesaid manufacturing method is employed, even in the case where the thickness of the coupling portion is made large (height is large), for example, the coupling portion is formed in a post shape so as to erect on the pattern wiring, the exfoliation of the coupling portion from the pattern wiring is prevented from occurring and so the reliability of the wiring board can be maintained.

In this manner, since the height of the coupling portion is made large, it becomes possible to improve the reliability in the case of mounting the coupling portions of a semiconductor chip and the wiring board with a fine pitch.

Further, when a semiconductor chip is mounted on the wiring board, it becomes possible to provide the semiconductor device in which a semiconductor chip is mounted on the wiring board with a fine coupling pitch and mounting reliability is good.

Next, the explanation will be made with reference to the accompanying drawings as to further concrete examples of a manufacturing method of a wiring board and a manufacturing method of a semiconductor device.

### First Embodiment

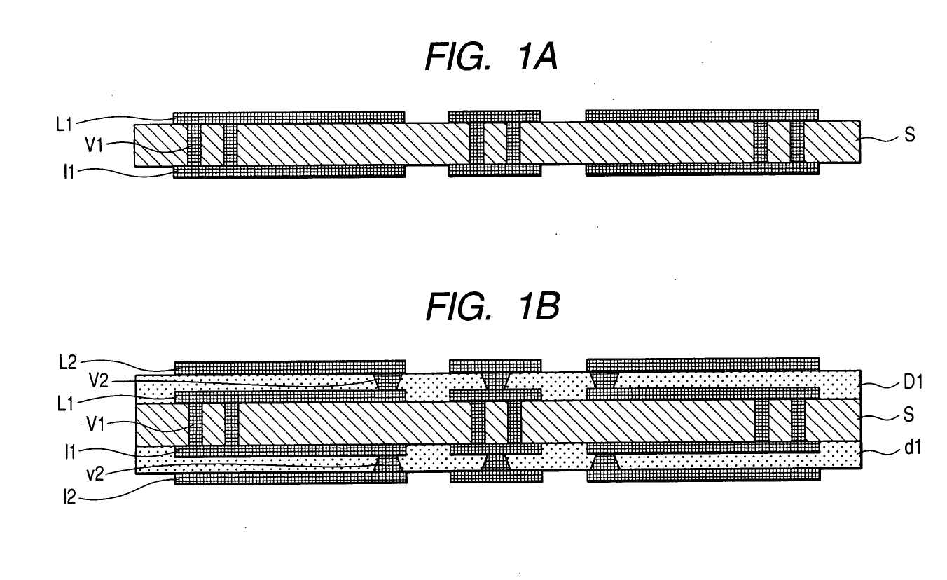

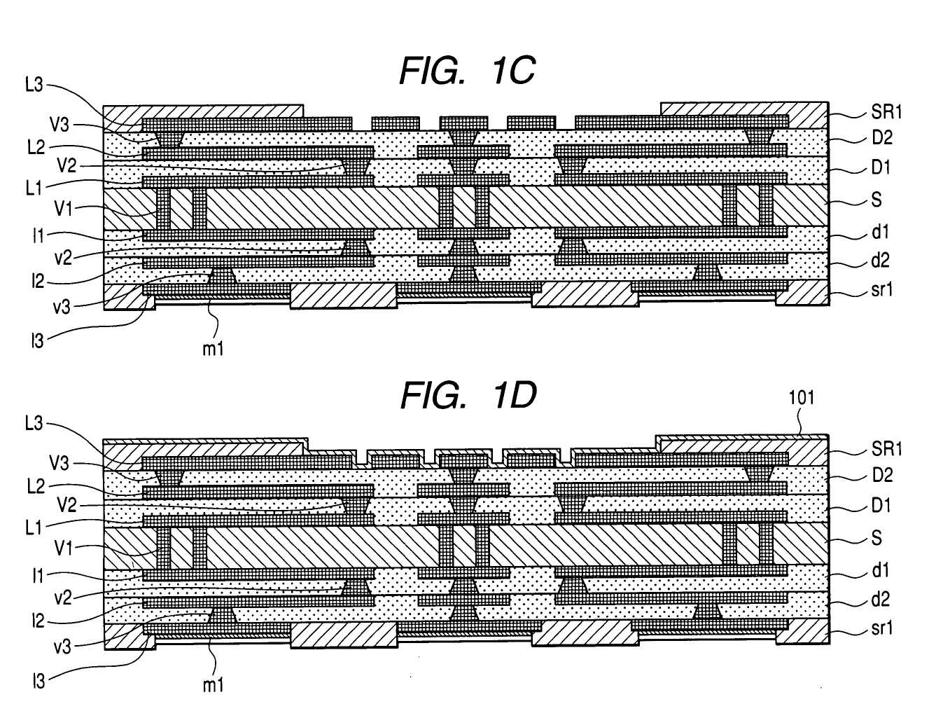

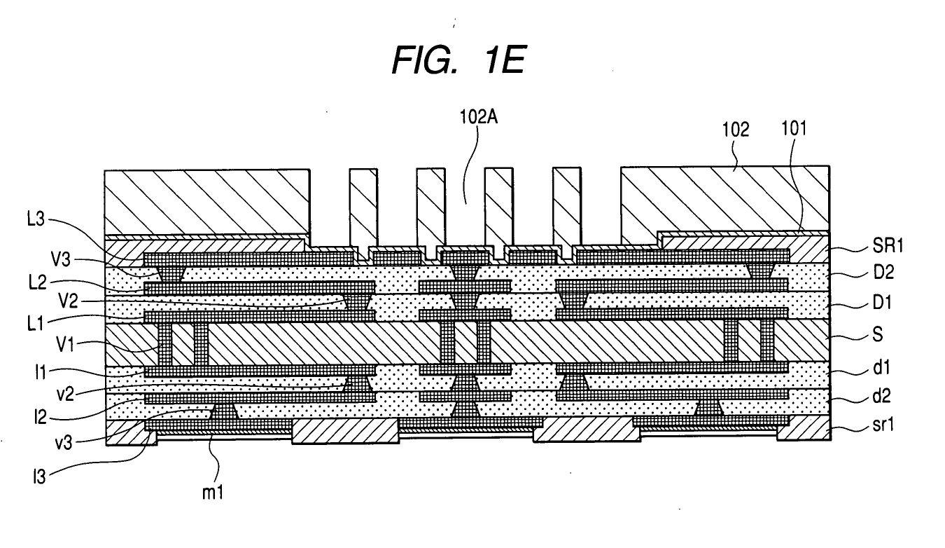

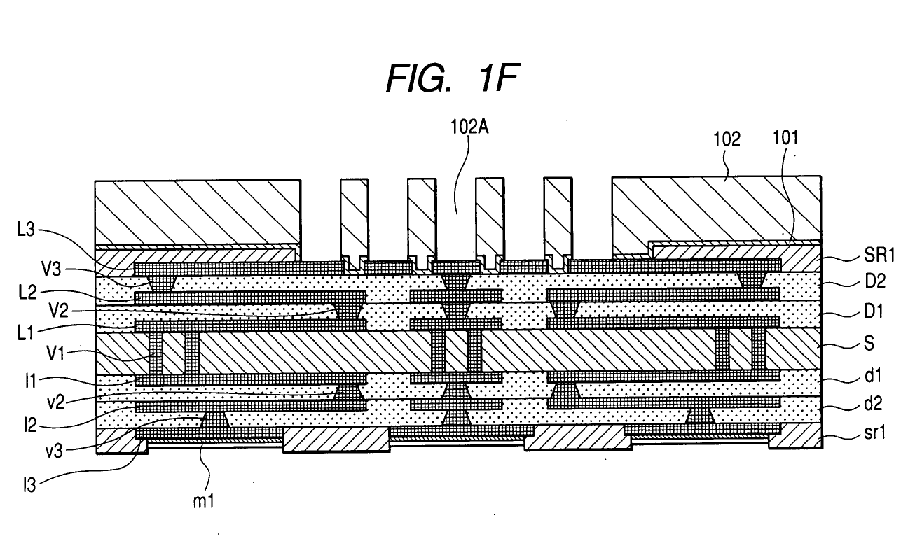

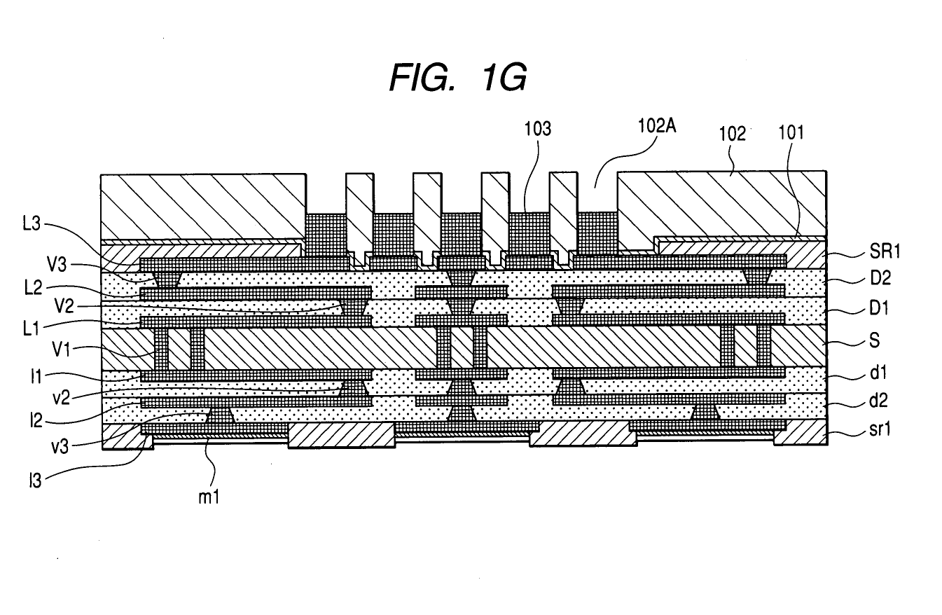

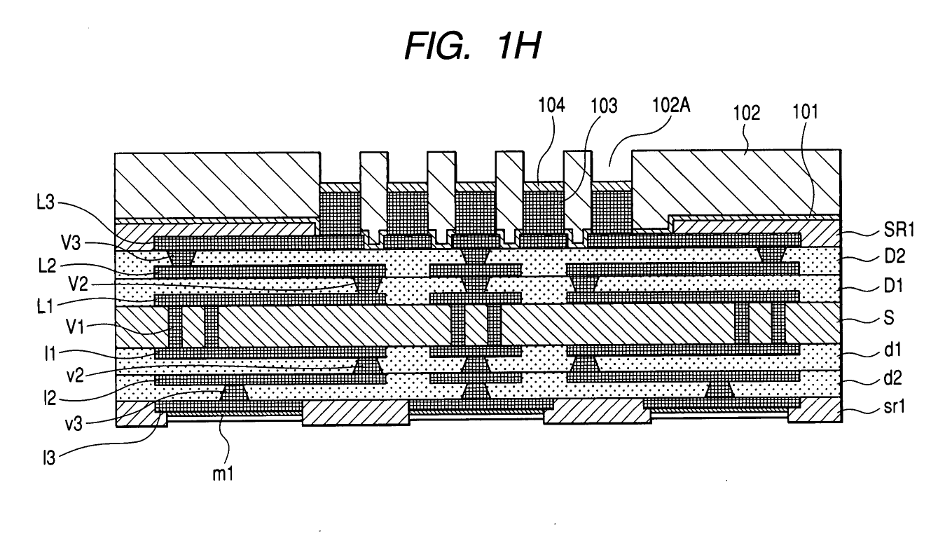

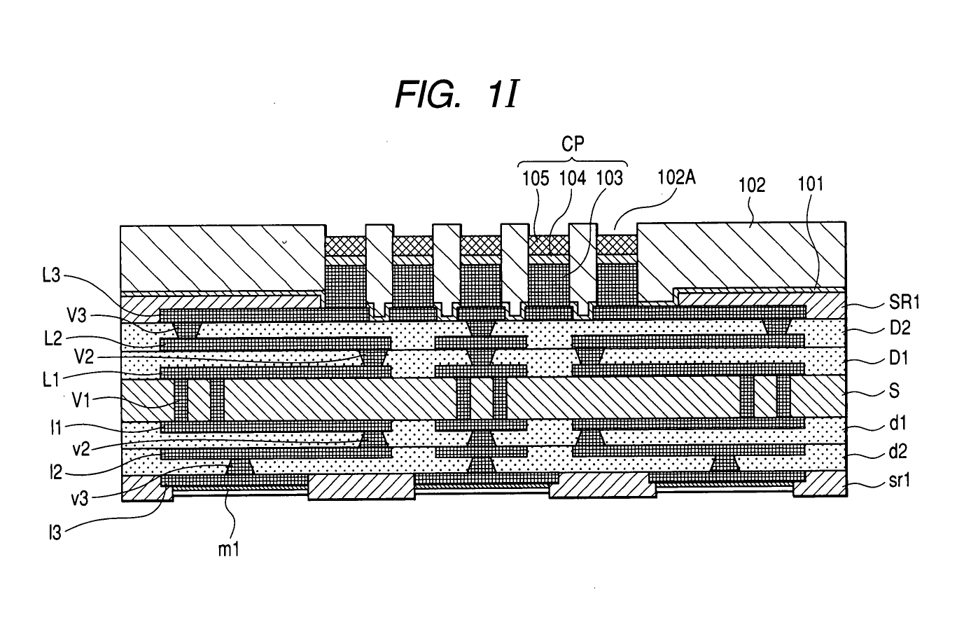

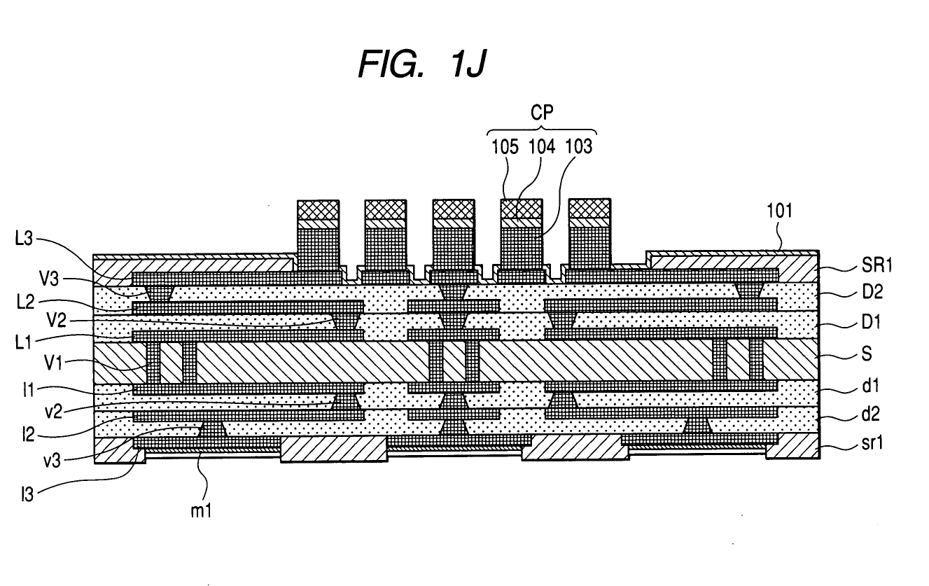

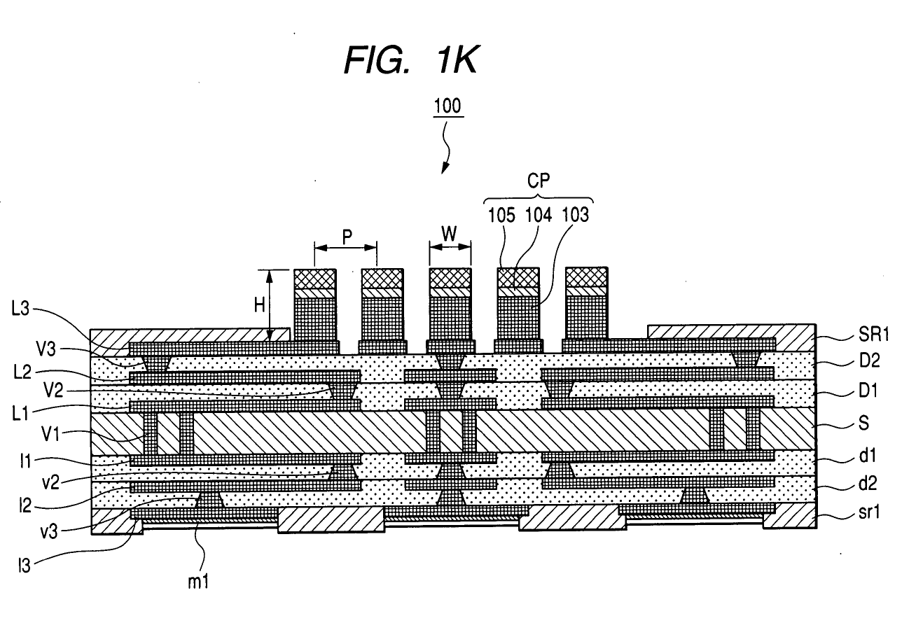

FIGS. 1A to 1K are diagrams for explaining the procedure of the manufacturing method of a wiring board according to the first embodiment of the invention. In the following explanation, portions identical to previously explained portions are referred to by the common symbols, with explanation thereof may being omitted.

First, in a process shown in FIG. 1A, via holes are formed at a core board S. Then, via plugs V1 penetrating the core board S and pattern wirings L1, l1 coupled to the via plugs V1 are formed according to the semi-additive method, for example. In this case, the pattern wirings L1 are formed on one side of the core board S (hereinafter this one side may be called as a first side) on which coupling portions to be coupled to a semiconductor chip are formed in the succeeding process, and the pattern wirings l1 are formed on a second side of the core board S in opposite to the first side.

Next, in a process shown in FIG. 1B, an insulation layer (build up layer) D1 is formed on the first side of the core board S so as to cover the pattern wirings L1. Further, via plugs V2 coupled to the pattern wirings L1 and pattern wirings L2 coupled to the via plugs V2 are formed according to the semi-additive method.

Similarly, an insulation layer (build up layer) d1 is formed on the second side of the core board S so as to cover the pattern wirings l1. Further, via plugs v2 coupled to the pattern wirings l1 and the pattern wirings 12 coupled to the via plugs v2 are formed according to the semi-additive method.

Next, in a process shown in FIG. 1C, a process similar to the process shown in FIG. 1B is performed. That is, an insulation layer (build up layer) D2 is formed so as to cover the pattern wirings L2. Further, via plugs V3 coupled to the pattern wirings L2 and the pattern wirings L3 coupled to the via plugs V3 are formed according to the semi-additive method.

Similarly, an insulation layer (build up layer) d2 is formed so as to cover the pattern wirings l2. Further, via plugs v3 coupled to the pattern wirings l2 and the pattern wirings l3 coupled to the via plugs v3 are formed according to the semi-additive method.

Further, an insulation layer (solder resist layer) SR1 is formed so as to cover a part of the insulation layer D2 and a part of the pattern wirings L3. Similarly, an insulation layer (solder resist layer) sr1 is formed so as to cover a part of the insulation layer d2 and a part of the pattern wirings l3. In this case, the insulation layer SR1 is not formed between the pattern wirings L3.

For example, L1 to L3, v1 to v3, l1 to l3 and v2 to v3 are formed by Cu.

Further, coupling layers m1 each formed by a Ni/Au plating layer, for example, may be formed on the pattern wirings l3 exposed on the insulation layer sr1.

Next, in processes shown in FIGS. 1D to 1K, coupling portions for mounting a semiconductor chip are formed on the structure shown in FIG. 1C.

First, in a process shown in FIG. 1D, a feeding layer 101 formed by Cu, for example, is formed by the nonelectrolytic plating method, for example, on the insulation layer SR1, the pattern wirings L3 exposed on the opening portions of the insulation layer SR1, and the insulation layer D2 exposed between the pattern wirings L3. The feeding layer 101 is a feeding layer for forming, by the electrolytic plating method, the coupling portions which are formed in the later processing so as to couple the pattern wirings L3 to the semiconductor chip. The feeding layer 101 is formed so as to have a thickness of 10μ or less, for example.

Next, in a process shown in FIG. 1E, a dry film resist, for example, is pasted on the feeding layer 101. Further, the dry film resist is patterned by the photo lithography method thereby to form a mask pattern 102 having opening portions 102A.

The positions, where the opening portions 102A are formed, correspond to positions where the coupling portions, for coupling the pattern wirings L3 to the semiconductor chip formed in the later processes (FIGS. 1G to 1I), are formed. In this case, the feeding layer 101 formed on the pattern wirings L3 exposes from the opening portions 102A.

Further, the mask pattern 102 is not limited to the dry film resist and may be formed by using a resist layer which is formed by the coating, for example.

Next, in a process shown in FIG. 1F, the feeding layer 101 on the pattern wirings L3 exposing from the opening portions 102A of the mask pattern 102 is etched away by using acid etchant, for example. In this case, when the feeding layer 101 exposing from the opening portions 102A is removed, the pattern wirings L3 expose from the opening portions 102A.

Next, in a process shown in FIG. 1G, the first layers 103 of the coupling portions formed by Cu, for example, are formed by the electrolytic plating method on the pattern wirings L3 exposing form the opening portions 102A. In this case, the first layers 103 are preferably formed by material (for example, Cu) same as that constituting the pattern wirings L3 since the adhesiveness between the pattern wirings L3 and the first layers 103 becomes preferable in particular.

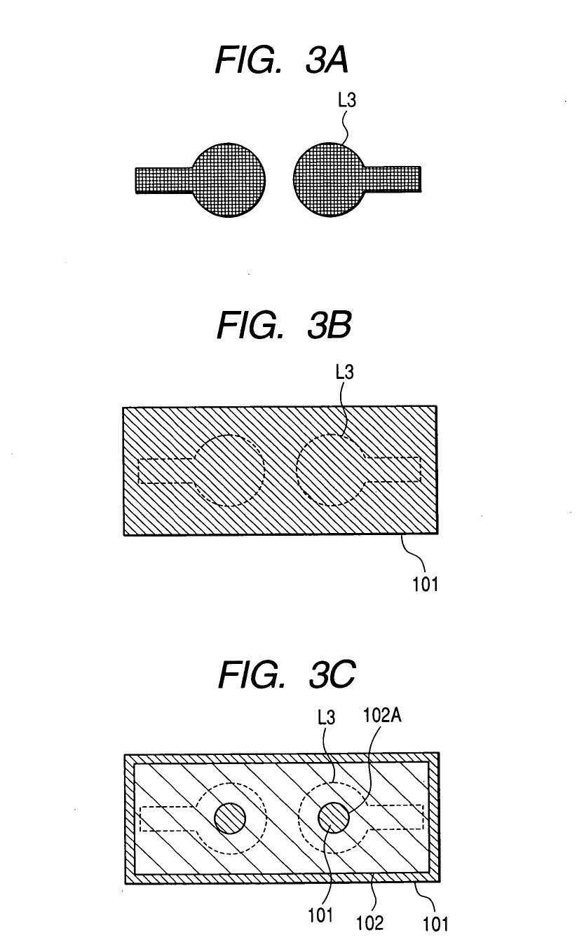

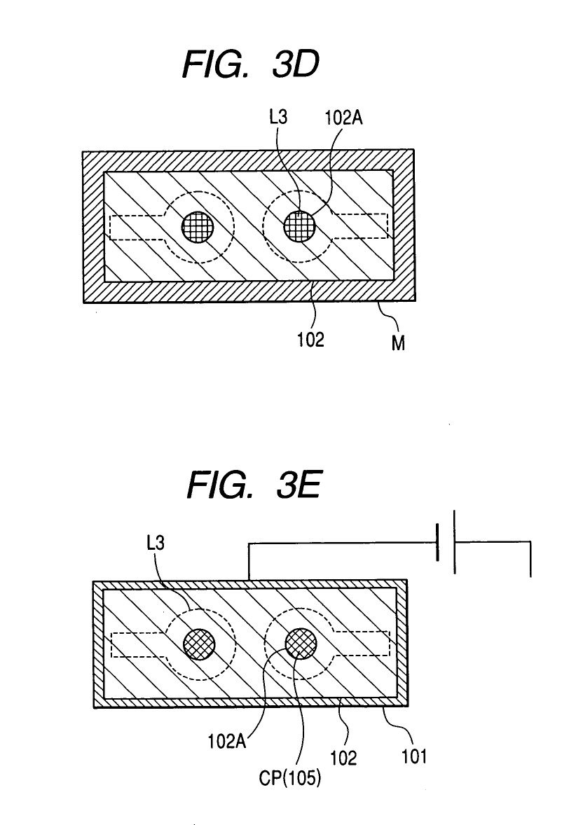

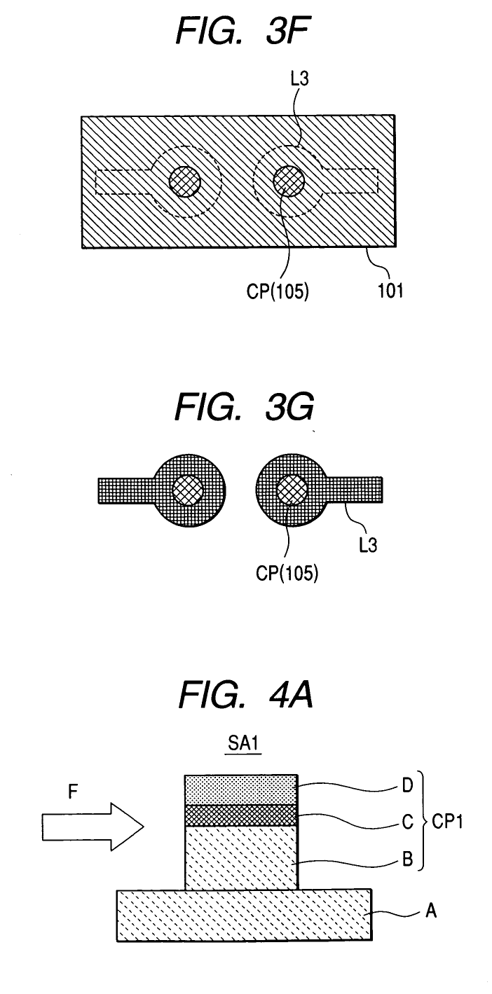

Further, in this case, since the electric power at the time of the electrolytic plating is fed via the feeding layer 101 not being etched away and the pattern wirings L3 coupled to the feeding layer 101, the first layer 103 can be formed by the electrolytic plating without causing any trouble. Such the positional relation between the feeding layer 101 and the pattern wirings L3 upon feeding the electric power will be explained with reference to FIG. 3A and so on.

Next, in a process shown in FIG. 1H, second layers 104 formed by Ni, for example, are formed on the first layers 103 by the electrolytic plating method. The second layer 104 has a function of improving the adhesiveness between the first layer 103 and a third layer 105 (described later) formed on the second layer 104.

Next, in a process shown in FIG. 1I, third layers 105 formed by solder (SnAgCu, for example), for example, are formed on the second layers 104 by the electrolytic plating method, thereby to form a coupling portion CP which is the lamination layer of the first layer 103, the second layer 104 and the third layer 105. The third layer 105 has a function of improving the coupling property between the coupling portion CP and the semiconductor chip.

Next, in a process shown in FIG. 1J, the mask pattern 102 is exfoliated and removed by using chemical such as NaOH.

Next, in a process shown in FIG. 1K, the unnecessary feeding layer 101 exposed in accordance with the removal of the mask pattern 102 is etched away by using acid etchant, for example.

In this manner, a wiring board 100 capable of mounting a semiconductor chip thereon can be formed.

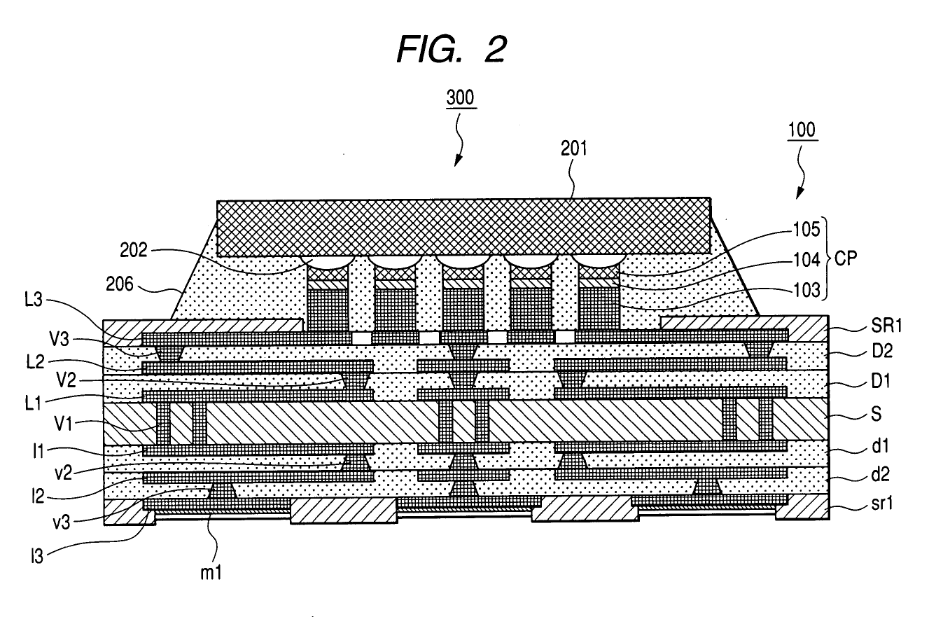

Further, when a procedure shown in FIG. 2 is executed after the process shown in FIG. 1K, a semiconductor device can be manufactured in which a semiconductor chip is mounted on the wiring board 100. In the following explanation, portions identical to previously explained portions are referred to by the common symbols, with explanation thereof being omitted.

In a process shown in FIG. 2, a semiconductor chip 201 is mounted on the wiring board 100. The semiconductor chip 201 has a structure that solder bumps 202 are formed on electrode pads (not shown), respectively, and is mounted on the wiring board 100 in a manner that the solder bumps 202 and the third layers 105 are coupled, respectively. In this case, the third layers 105 are surely coupled electrically to the solder bumps 202, respectively, by the reflow soldering or ultrasonic bonding and so on, for example.

Thereafter, under fill 206 made of resin permeates between the semiconductor chip 201 and the wiring board 100, whereby a semiconductor device 300 can be formed.

In the manufacturing process of the wiring board 100 (semiconductor device 300), the coupling portions CP to be coupled to the semiconductor chip 201 are formed by the electrolytic plating method at the portions where the feeding layer 101 is removed on the pattern wirings L3. Thus, since the adhesiveness between the coupling portion CP and the pattern wiring L3 is good, the coupling portion CP is prevented from being exfoliated from the pattern wiring L3 and so the structured is stable. Therefore, the wiring board 100 (semiconductor device 300) has a feature that the reliability in the case of mounting the semiconductor chip 201 is good.

Further, in the wiring board 100 (semiconductor device 300), each of the coupling portions CP is formed in a post shape so as to erect on the pattern wiring L3. Conventionally, since the adhesive force between the coupling portion and the pattern wiring is small, it is difficult to maintain the mounting reliability of the wiring board (semiconductor device) in the structure where a force applied on the boundary surface between the coupling portion and the pattern wiring is large.

In the wiring board 100 (semiconductor device 300) according to the embodiment, since the wiring board (semiconductor device) is formed by the aforesaid manner, the adhesive force between the coupling portion and the pattern wiring becomes large. Thus, the coupling portion CP can be formed in the post shape so as to erect on the pattern wiring L3 and the mounting reliability can be maintained. As a result, the semiconductor chip can be mounted with a fine coupling pitch as explained below.

For example, when the pitch of the coupling portions of the semiconductor chip and the wiring board is made fine, the size of the coupling portions such as the solder bumps is forced to be small. As a result, the clearance between the semiconductor chip and the wiring board becomes small. Thus, since the under fill made of resin hardly permeates, there arises such a problem that voids are generated in the under fill thereby to degrade the mounting reliability. In the wiring board 100 (semiconductor device 300), since each of the coupling portions CP is formed in the post shape so as to erect on the pattern wiring L3, the clearance between the semiconductor chip and the wiring board becomes large. Thus, the under fill likely permeate, so that the generation of the voids is suppressed in the under fill and so the mounting reliability is improved.

Further, the wiring board 100 (semiconductor device 300) has a feature that each of the portions (hereinafter called a melting portion) such as solder bumps which are molten and coupled are separated from the insulation layer and the solder resist layer. Thus, the melting portions hardly bridge (short-circuit) over the insulation layer and the solder resist layer. As a result, in particular, the mounting reliability in the case of forming the coupling portions with a fine pitch can be improved advantageously. Further, the volume of the melting portion such as the solder can be reduced as compared with the related art advantageously.

The aforesaid wiring board 100 (semiconductor device 300) can be formed in a manner as shown in FIG. 1K that, for example, the setting pitch P of the coupling portions CP is 100 μm or less, the diameter W of the coupling portion CP is 50 μm or less, and the height H of the coupling portions CP is in a range of 30 to 100 μm. In this case, if the height H of the coupling portions CP is larger than the diameter W of the coupling portion CP, the aforesaid effect that the mounting reliability in the case of forming the coupling portions CP with the fine pitch is improved further advanced preferably.

Further, for example, the wiring board is formed in a manner that the thickness of the first layer 103 is 35 μm, the thickness of the second layer is 1 μm, and the thickness of the third layer is 20 μm, but these thicknesses merely represent one example and the invention is not limited thereto.

Next, the manufacturing method of the wiring board (semiconductor device) as explained above will be explained based on figures in which the wiring board is seen from the side where the semiconductor chip is mounted.

FIGS. 3A to 3G are typical diagrams each showing a state in which the wiring board is seen from the side where the semiconductor chip is mounted, as to the manufacturing method of the wiring board (semiconductor device) as explained in FIGS. 1A to 1K and 2. In these figures, portions identical to previously explained portions are referred to by the common symbols, with explanation thereof being omitted partly. Further, in the following drawings, a particular one of the many pattern wirings L3 is schematically shown in an enlarged manner and a part (for example, the insulation layer and the peripheral structure etc.) thereof is omitted from being illustrated.

First, a process shown in FIG. 3A corresponds to the process shown in FIG. 1C. In this figure, the pattern wiring L3 where the lands are formed is seen form the side where the semiconductor chip is mounted.

Next, a process shown in FIG. 3B corresponds to the process shown in FIG. 1D. In this process, the feeding layer 101 formed by Cu, for example, is formed on the pattern wiring L3 by the nonelectrolytic plating method, for example.

Next, a process shown in FIG. 3C corresponds to the process shown in FIG. 1E. In this process, the mask pattern 102 having the opening portions 102A is formed on the feeding layer 101. The feeding layer 101 exposes from the opening portion 102A.

Next, a process shown in FIG. 3D corresponds to the process shown in FIG. 1F. In this process, the feeding layer 101 exposing from the opening portions 102A of the mask pattern 102 is etched away. In this case, since the feeding layer 101 is removed, the pattern wirings L3 expose from the opening portions 102A. Before this process, the peripheral portion (not shown in FIG. 1F) of the feeding layer 101 not being covered by the mask pattern 102 is preferably covered by a mask M (not shown in FIG. 1F) before the etching process.

Next, a process shown in FIG. 3E corresponds to the processes shown in FIGS. 1G to 1I. In this process, the coupling portions CP are formed on the pattern wirings L3 exposed from the opening portions 102A by the electrolytic plating method. In this case, the third layer 105, which is the uppermost layer of the coupling portion CP, is seen from the opening portion 102A.

Before this process, the mask M formed in the process shown in FIG. 3D is exfoliated thereby to expose the peripheral portion of the feeding layer 101 (not shown in FIGS. 1G to 1I), and the voltage is applied to the feeding layer 101 from the peripheral portion.

In this process, as explained above, since the electric power at the time of the electrolytic plating is fed via the feeding layer 101 not being etched away and the pattern wirings L3 (formed so as to be partially overlapped with the feeding layer 101) coupled to the feeding layer 101, the coupling portions CP can be formed by the electrolytic plating without causing any trouble.

Next, a process shown in FIG. 3F corresponds to the processes shown in FIGS. 1J. In this process, the mask pattern 102 is exfoliated and removed by using chemical such as NaOH. Thus, the feeding layer 101 not being etched away exposes.

Next, a process shown in FIG. 3G corresponds to the processes shown in FIGS. 1K. In this process, the unnecessary feeding layer 101 exposed in accordance with the removal of the mask pattern 102 is etched away by using acid etchant, for example. In this manner, the wiring board 100 is formed.

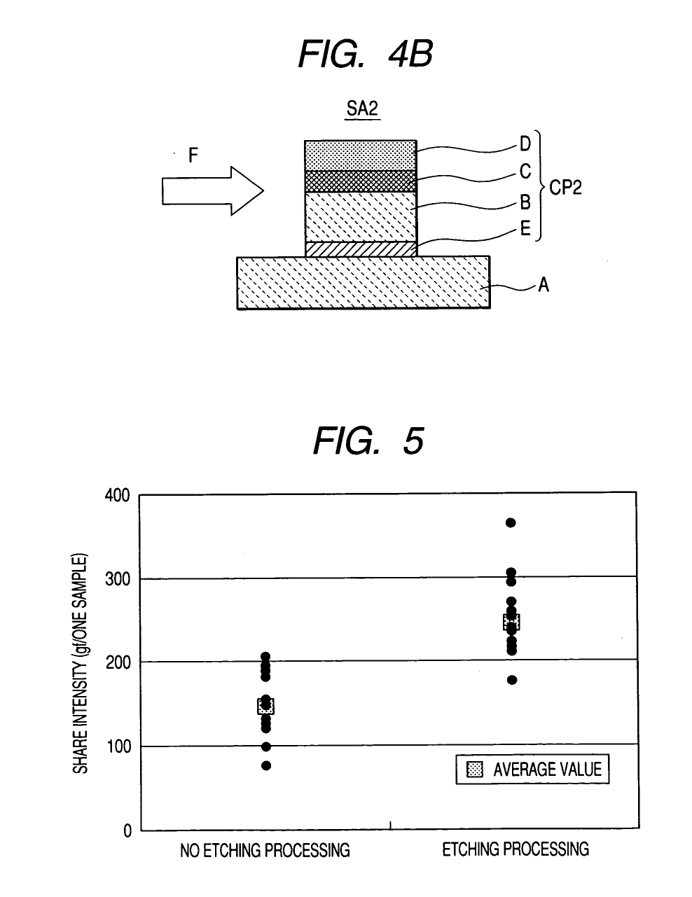

Next, in order to test the reliability of the coupling portions of the wiring board (semiconductor device) formed by the aforesaid manufacturing method, test samples SA1, SA2 respectively shown in FIGS. 4A and 4B are formed and the adhesive force test is executed.

FIGS. 4A and 4B are diagrams schematically showing the test samples for testing the adhesive force of the coupling portion of the wiring board (semiconductor device).

FIG. 4A is a diagram showing the sample SA1 which is formed on the assumption that it is the coupling portion formed by the manufacturing method according to the aforesaid embodiment.

Referring to FIG. 4, the sample SA1 has the structure that, on a flat plate A (supposing the wire L3) formed by Cu, a coupling portion CP1 (supposing the aforesaid coupling portion CP) formed by laminating a first layer B (supposing the first layer 103) formed by Cu, a second layer C (supposing the second layer 104) formed by Ni and a third layer D (supposing the third layer 105) formed by solder is formed.

FIG. 4B is a diagram showing a sample SA2 which is used for the comparison with the sample SA1 and is formed by supposing the coupling portion formed by the conventional method. In this figure, portions identical to previously explained portions are referred to by the common symbols, with explanation thereof being omitted. The sample SA2 differs from the sample SA1 in a point that a coupling portion CP2 corresponding to the coupling portion CP1 has a lower layer E (supposing the feeding layer 101) formed by the nonelectrolytic plating. The layer E is formed between the first layer B and the flat plate A.

In the adhesive force test, a plurality of the samples SA1 and a plurality of the samples SA2 are formed, then a force is applied to these samples in the lateral direction (direction in parallel to the flat plate A), and a force F for exfoliating the coupling portions CP1, CP2 from the flat plate. As a result, it becomes possible to compare the adhesive forces of the respective coupling portions as described below.

FIG. 5 is a diagram showing the result of the aforesaid adhesive force test. In the figure, the expression “etching processing” represents the result of the sample SA1 and “no etching processing” represents the result of the sample SA2. Further, in the figure, an ordinate represents a value which is obtained by converting a force F at the time of exfoliating the sample into a value per one sample.

Referring to FIG. 5, although there are variations in the adhesive force, it will be understood that the adhesive force of the sample SA1 exceeds the adhesive force of the sample SA2 when compared them as to the average values of the adhesive force of these samples. Accordingly, it is confirmed that the adhesive force of the coupling portion formed according to the embodiment is good which is featured that, in the case of forming the coupling portions on the wiring, the feeding layer is etched away and the patterning is performed by directly performing the electrolytic plating on the wirings.

Although the aforesaid embodiments are explained as to an example where a core board is used as the wiring board, the invention is not limited thereto. It is apparent that the invention can be applied to a wiring board in which all layers are formed by a so-called build-up method, for example. Further, the number of the layers and the wiring structure of the wiring layer may be suitably changed and modified.

Although the invention is explained as to the preferable embodiment as described above, the invention is not limited to the aforesaid particular embodiment and may be modified and changed in various manners within the gist recited in claims.

According to the invention, it is possible to provide the wiring board which is good in mounting reliability and capable of mounting a semiconductor chip with a fine coupling pitch and also to provide the semiconductor device in which a semiconductor chip is mounted on the wiring board with a fine coupling pitch and mounting reliability is good.

What is claimed is:

1. A method of manufacturing a wiring board, for mounting a semiconductor chip thereon, including coupling portions to be coupled to the semiconductor chip and a pattern wiring to be coupled to the semiconductor chip via the coupling portions, comprising:
a feeding layer forming step of forming, on the pattern wiring, the feeding layer used for forming the coupling portions by an electrolytic plating method;
a masking step of forming a mask pattern on the feeding layer;
an etching step of etching the feeding layer exposed from the mask pattern; and
an electrolytic plating step of forming the coupling portions on the pattern wiring exposed from the mask pattern by an electrolytic plating method.

2. The method of manufacturing a wiring board according to claim 1, wherein
each of the coupling portions is formed by laminating a plurality of layers by an electrolytic plating method.

3. The method of manufacturing a wiring board according to claim 2, wherein
the coupling portion includes a lowermost layer formed by same material as the pattern wiring, and
the lowermost layer is formed so as to contact to the pattern wiring.

4. The method of manufacturing a wiring board according to claim 1, wherein
the coupling portion is formed so as to erect on the pattern wiring.

5. The method of manufacturing a wiring board according to claim 4, wherein
a height of the coupling portion is larger than a diameter of the coupling portion.

6. The method of manufacturing a wiring board according to claim 1, wherein
the feeding layer is formed on the pattern wiring and on an insulation layer covering a part of the pattern wiring.

7. The method of manufacturing a wiring board according to claim 1, further comprising:
a step of, after the electrolytic plating step, removing the mask pattern and etching away the feeding layer which is exposed in accordance with the removal of the mask pattern.

8. A method of manufacturing a semiconductor device, for mounting a semiconductor chip on a wiring board, including the semiconductor chip, coupling portions to be coupled to the semiconductor chip and a pattern wiring to be coupled to the semiconductor chip via the coupling portions, comprising:
a feeding layer forming step of forming, on the pattern wiring, the feeding layer used for forming the coupling portions by an electrolytic plating method;
a masking step of forming a mask pattern on the feeding layer;
an etching step of etching the feeding layer exposed from the mask pattern;
an eletrolytic plating step of forming the coupling portions on the pattern wiring exposed from the mask pattern by an electrolytic plating method; and
a mounting step of coupling the semiconductor chip to the coupling portions.

9. The method of manufacturing a semiconductor device according to claim 8, wherein
the coupling portion is formed so as to erect on the pattern wiring.

10. The method of manufacturing a semiconductor device according to claim 8, wherein
the coupling portion is formed by laminating a plurality of layers by an electrolytic plating method, and
one of the plurality of layers coupled to the semiconductor chip is formed by material different from material forming another of the plurality of layers coupled to the wiring pattern.
